(19) United States
(12) Patent Application Publication
(10) Pub. No.: US 2006/0264066 A1
(43) Pub. Date: Nov. 23, 2006

(54) Multilayer multicomponent high-k films and methods for depositing the same

(75) Inventors: Larry D. Bartholomew, Felton, CA (US); Helmuth Treichel, Milpitas, CA (US); Jon S. Owyang, San Jose, CA (US)

Correspondence Address: Tianjun Hou;Dorsey & Whitney LLP, Intellectual Property Department, 555 California Street, Suite 1000, San Francisco, CA, 94104-1513, US

(73) Assignee: AVIZA TECHNOLOGY, INC.

(21) Appl. No.: 11/400,366

(22) Filed: Apr. 7, 2006

Related U.S. Application Data
(60) Provisional application No. 60/669,812, filed on Apr. 7, 2005.

(51) Int. Cl. H01L 21/31; H01L 23/58

(52) U.S. Cl. 438/785; 257/632

(57) ABSTRACT

The present invention provides systems and methods for forming a multi-layer, multi-component high-k dielectric film. In some embodiments, the present invention provides systems and methods for forming high-k dielectric films that comprise hafnium, titanium, oxygen, nitrogen, and other components. In a further aspect of the present invention, the dielectric films are formed having composition gradients.

### CROSS REFERENCE TO RELATED APPLICATIONS

This application claims benefit of priority under 35 U.S.C. § 119(e) to U.S. Provisional Patent Application No. 60/669,812 filed Apr. 7, 2005, the disclosure of which is incorporated herein by reference in its entirety.

### FIELD OF THE INVENTION

In general, the present invention relates to systems and methods for forming high-k dielectric films in semiconductor applications. More specifically, the present invention relates to systems and methods for fabricating multi-component dielectric films comprising hafnium, titanium, oxygen, nitrogen and other components on a substrate.

### BACKGROUND OF THE INVENTION

The requirements for increased performance and speed provide some of the driving forces for the continuing scaling of microelectronic devices. Additionally, the expectations of higher performance, increased features, and lower costs from the end users provide a driving force to accomplish the scaling in an economic manner. These forces have combined to establish the trend that the number of transistors on a semiconductor device doubles approximately every 18 months. This is the well known “Moore's Law” of semiconductor device scaling.

The speed and performance of the transistor are largely dictated by the details of the gate engineering. This includes the details of the source and drain depth and doping, the thickness and nature of the gate dielectric materials, and other factors. Current leading edge technology continues to use silicon dioxide as the gate dielectric material. To prevent issues such as boron penetration, the silicon dioxide gate material is often doped with nitrogen. To meet the device speed requirements, the thickness of the silicon dioxide gate dielectric material is approaching <1 nm. It is predicted that at the semiconductor device node known as the “45 nm node” (defined in the International Technology Roadmap for Semiconductors—ITRS), the required thickness of silicon dioxide will not be sufficient to prevent the “tunneling” of electrons through the gate dielectric material. Under these conditions, known devices will no longer function.

The structure of the conventional transistor gate is that of a multilayer stack. The current technology applies a silicon dioxide gate dielectric material (optionally doped with nitrogen) on a bare silicon surface. Generally, an electrode material such as doped poly-silicon (optionally tungsten or metal silicides) is deposited on top of the gate dielectric material. The gate dielectric material must be chemically, physically, and electrically stable when in contact with both the substrate and the electrode material under subsequent processing steps that may include high temperatures, typically 600° C. and above, during the manufacture of the semiconductor device. Silicon dioxide has been uniquely well suited for this application for over 40 years.

Similar issues are faced in the formation of capacitor structures in semiconductor devices. There are generally three basic types of capacitors. “SIS” capacitors refer to silicon-insulator-silicon capacitors where the electrodes are each made of doped silicon. “MIS” capacitors refer to metal-insulator-silicon capacitors where one electrode is a metal and the other electrode is made from doped silicon. Finally, “MIM” capacitors refer to metal-insulator-metal capacitors where the electrodes are each made of metal with dielectrics embedded between layers of barriers, such as CoWP, Ta/TaN, Ti/TiN, Ru/RuO₂, followed by the actual electrodes such Cu, Ru, etc. depending on the type of device. As with the gate dielectric material mentioned above, the dielectric material must be chemically, physically, and electrically stable when in contact with both of the electrode materials under subsequent processing steps that may include high temperatures, typically 600° C. and above, during the manufacture of the semiconductor device. Silicon dioxide and silicon nitride have been uniquely well suited for this application for many years. However, the requirement for increased memory density and smaller memory cells require that new technologies be developed for capacitor applications.

Research has been devoted to identifying and developing new materials with a higher dielectric permittivity “high-k” to replace the silicon dioxide dielectric material. This would allow the device to function while preventing the tunneling of electrons. Generally, metal oxide materials such as ZrO₂ and HfO₂ have been investigated. These materials have been found to be unsatisfactory for several reasons. These metal oxides materials are not stable under subsequent processing conditions when deposited on silicon or silicon dioxide. They react with underlying materials and the electrode materials to form oxide and silicate phases that do not have the desired dielectric properties and degrade the performance of the device. Additionally, it has been found that they exhibit high “leakage current” and lead to devices that consume more power than typical devices. This is undesirable for devices that will be used in applications where long battery life is required.

Accordingly, there is a need for further developments in methods of fabricating films with a higher value of the dielectric constant (high-k) than silicon dioxide. There is particularly a need for a method of fabricating high k films using advanced deposition techniques such as atomic layer deposition (ALD) and the like.

### BRIEF SUMMARY OF THE INVENTION

In general, the present invention provides for methods for deposition of a multi-component film material with a dielectric constant (high-k) higher than that of SiO₂. The high-k material finds uses in the manufacture of semiconductor structures such as gates, capacitors, and the like. In some embodiments, the methods provide for the introduction of a composition gradient throughout the film during the deposition process.

In one embodiment, the present invention provides for methods for deposition of a multi-layer, multi-component film stack with a dielectric constant (high-k) higher than that of SiO₂. The high-k film stack finds uses in the manufacture of semiconductor structures such as gates, capacitors, and the like. The methods provide for the introduction of a composition gradient throughout each of the films in the film stack during the deposition process for that film.

In one embodiment of the present invention, various deposition methods are used to form the multi-component film materials. The deposition methods include sequential thermal ALD, sequential plasma-enhanced ALD, co-injection thermal ALD, co-injection plasma-enhanced ALD, thermal Chemical Vapor Deposition (CVD), plasma-enhanced CVD, or Physical Vapor Disposition (PVD), as described in detail below.

In another embodiment of the present invention, a multi-component film of a high-k material is provided comprising hafnium, titanium, silicon, oxygen, nitrogen, and combinations thereof. The high-k material may be used in the manufacture of semiconductor structures such as gates, capacitors, and the like.

In one embodiment of the present invention, the multi-component films are formed by providing suitable precursors containing the various components of the multi-component film. The precursors may be distinct chemical entities or may be appropriate mixtures of two or more components. The precursors may be introduced either simultaneously or sequentially during deposition. In an exemplary embodiment, precursors containing hafnium, titanium, and silicon are used.

In a further embodiment of the present invention, the multi-component films are formed by providing suitable reactant gases containing the various components of the multi-component films. The reactant gases comprise various chemical species that can be used to oxidize, nitride, or reduce the deposited layer. The reactant gases may be introduced either simultaneously or sequentially during the deposition.

In another embodiment of the present invention, multi-layer, multi-component film stacks forming a high-k gate film stack are provided. In some embodiments, the multi-layer high-k stack comprises Si-rich layers, first barrier layers, bulk high-k layers, oxy-nitride layers, second barrier layers, electrode layers, and combinations thereof. Optionally, one or more of the layers are selected and developed to specifically optimize the performance of the multi-layer structure.

In one embodiment of the present invention, multi-layer, multi-component film stacks forming a high-k capacitor film stack are provided. In some embodiments, the multi-layer stack comprises first barrier layers, electrode layers, second barrier layers, bulk high-k layers, third barrier layers, electrode layers, and combinations thereof. Further, one or more of the layers may be selected and developed to specifically optimize the performance of the multi-layer structure.

Aspects of the invention also provide a method of forming a film on a substrate, characterized in that two or more precursors, at least one of the precursors containing a titanium containing chemical component, are conveyed to a process chamber together or sequentially and form a mono-layer on a surface of the substrate, wherein the amount of each of the precursors conveyed to the process chamber is selectively controlled such that a desired composition gradient is formed in the film.

### BRIEF DESCRIPTION OF THE DRAWINGS

Other aspects, embodiments and advantages of the invention will become apparent upon reading of the detailed description of the invention and the appended claims provided below, and upon reference to the drawings in which:

FIG. 1 is a schematic cross-sectional view of a gate dielectric stack illustrating one embodiment of the present invention; and

FIG. 2 is a schematic cross-sectional view of a capacitor dielectric stack illustrating one embodiment of the present invention.

### DETAILED DESCRIPTION OF THE INVENTION

In general, the present invention provides for methods for deposition of a multi-component film material with a dielectric constant (high-k) higher than that of SiO₂. The high-k material finds uses in the manufacture of semiconductor structures such as gates, capacitors, and the like. The methods provide for the introduction of a composition gradient throughout the film during the deposition process. The method of present invention is illustrated with embodiments where a silicon wafer is used as the substrate. It will be appreciated that the method may be used to deposit films on any suitable substrates such as silicon wafers, compound semiconductor wafers, glasses, flat panels, metals metal alloys, plastics, polymers organic materials, inorganic materials, and the like.

In one embodiment, the present invention provides a dielectric film comprising a composition of HfTiSiₓO_{y}N_{z} wherein x, y, and z represent a number from 0 to 2, respectively. The dielectric film may be used in the manufacturing of semiconductor structures such as gates, capacitors, and so on.

In one embodiment, the dielectric film of the present invention comprises a hafnium component, a titanium component, a silicon component, an oxygen component, and a nitrogen component.

In one exemplary embodiment of the present invention, HfSiTiOₓ films are formed. In some embodiments, a film stack is provided wherein the bottom (first few layers) of the film contains a Si concentration that is higher than the concentration of Hf or Ti, or Hf and Ti (e.g. [Si]>>([Hf+Ti])), referred to herein as “Si-rich”. This is a desirable attribute of the film because a Si-rich film has increased stability when deposited directly on bare Si or SiO₂ during subsequent thermal processing during the manufacture of a semiconductor device. However, a high concentration of Si is known to decrease the k-value of these types of dielectric materials. One example of an ALD technique that may be used to deposit this film structure is described in the pending U.S. patent application Ser. No. 10/869,779 filed Jun. 15, 2004 (Attorney Docket No. A-72218-1/MSS), which is incorporated herein by reference in its entirety. In one embodiment, ALD methods form multi-component films by introducing precursors containing each component during one portion of the ALD deposition cycle. Reactant gases such as chemical species that can be used to oxidize, nitride, or reduce the precursors are then introduced during other portions of the ALD deposition cycle. In the following description, the present invention is described with exemplary embodiments where an oxidizing reactant is used. It will be appreciated that suitable nitriding or reducing reactant gases may also be used depending upon the desired film to be deposited.

The relative concentrations of the Si, Hf, and Ti are selectively controlled or altered as the film thickness is increased by successive applications of selectively controlling or altering the deposition parameters of the various precursors during each cycle. Deposition parameters include carrier gas flow rate, pulse time, and the like. In this way, the Si concentration of the film can be selected to be high at the beginning of the deposition of the film and decreased to zero at the middle or top of the film. This has the effect of promoting stability of the high-k dielectric film in contact with the underlying Si or SiO₂ layer and yet, maximizing the k-value of the film.

In one embodiment of the present invention, deposition precursors comprising at least one deposition metal having the following formula are used:

where M is a metal including Hf and Ti; L is a ligand including amine, amides, alkoxides, halogens, hydrides, alkyls, azides, nitrates, nitrites, cyclopentadienyls, carbonyl, carboxylates, diketonates, alkenes, alkynes, or a substituted analogs thereof, and combinations thereof; and x is an integer less than or equal to the valence number for M. In an exemplary embodiment, the Hf precursor is TEMA-Hf and the Ti precursor is TEMA-Ti where the TEMA ligand is the tetrakis(ethylmethylamino) ligand. A third, Si containing precursor is also used. Suitable sources of Si include silicon halides, silicon dialkyl amides or amines, silicon alkoxides, silanes, disilanes, siloxanes, aminodisilane, and disilicon halides. In an exemplary embodiment, the silicon precursor is TEMA-Si where the TEMA ligand is the tetrakis(ethylmethylamino) ligand.

The three precursors (TEMA-Hf, TEMA-Ti, and TEMA-Si) are introduced into the process chamber. The process chamber may be adapted to hold a single substrate such as in a single-wafer system or the like, or the process chamber may be adapted to hold a plurality of substrates such as in a batch furnace, a mini-batch furnace, a multi-wafer processing system, or the like. A mini-batch furnace that is particularly well suited to practice the present invention is described in U.S. patent application Ser. No. 10/521,619 filed Jan. 14, 2005 (Attorney Docket No. A-71748/MSS), which is incorporated herein by reference in its entirety. While certain exemplary deposition systems are shown, the method of the present invention may be carried out in any variety of ALD, CVD and PVD systems known in the art. The three precursors are introduced into the process chamber in a sequential manner. The three precursors form a monolayer on the substrate(s) in a concentration proportional to their gas phase concentration and their surface reactivity. Excess precursor that does not form the monolayer is removed from the process chamber by any suitable means. A suitable oxidizing reactant is then introduced to react with the monolayer. The oxidizing reactant can be ozone, oxygen, peroxides, water, air, nitrous oxide, nitric oxide, N-oxides, and mixtures thereof. Ozone and water are exemplary choices. Excess oxidizing reactant that does not react with the monolayer is removed from the process chamber by any suitable means. The result is a HfSiTiOₓ layer with a specific relative concentration of Hf, Si, and Ti. During the next sequential cycle, the relative concentration in the gas phase of the three precursors may be changed by changing the process parameters of the three precursors. This results in a second monolayer with a different relative concentration of Hf, Si, and Ti from the first. This teaching may be employed during each cycle of the deposition process to tailor the concentration of each component throughout the film.

In some embodiments, the sequential ALD method described above is typically practiced at temperatures between 20° C. and 800° C., and preferably between 150° C. and 400° C. The sequential ALD method described above is typically practiced at pressures between 0.001 mTorr and 600 Torr, and preferably between 1 mTorr and 100 Torr. The sequential ALD method cited above is typically practiced at total gas flow rates between 0 sccm and 20,000 sccm, and preferably between 0.1 sccm and 5000 sccm.

In another exemplary embodiment of the present invention, it is desirable to practice the present invention at temperatures below 200° C. Additional energy source is supplied to facilitate the reaction and compound formation. In this embodiment, the three precursors (TEMA-Hf, TEMA-Ti, and TEMA-Si) are introduced sequentially into the process chamber. As before, the process chamber may hold a single substrate or a plurality of substrates. Excess precursor that does not form the monolayer is removed from the process chamber by any suitable means. As before, a suitable oxidizing reactant is then introduced to react with the monolayer. Ozone and water are exemplary choices. To facilitate the reaction, an energy source is used. The energy source may be direct plasma, remote plasma, down-stream plasma, RF-plasma, microwave plasma, UV photons, vacuum UV (VUV) photons, visible photons, IR photons, and combinations thereof. The energy source forms a chemical species that is reactive at temperatures of <200° C. The energy source may be used directly in the process chamber or may act upon the reactant gas before it enters the process chamber. The inventors have characterized this method as “Energy-assisted sequential ALD.” Excess oxidizing reactant that does not react with the monolayer is removed from the process chamber by any suitable means. The result is a HfSiTiOₓ layer with a specific relative concentration of Hf, Si, and Ti. During the next ALD cycle, the relative concentration in the gas phase of the three precursors may be changed by changing the process parameters of the three precursors. This results in a second monolayer with a different relative concentration of Hf, Si, and Ti from the first. This teaching may be employed during each cycle of the deposition process to tailor the concentration of each component throughout the film.

The energy-assisted sequential ALD method cited above is typically practiced at temperatures between 20° C. and 800° C., and preferably between 20° C. and 200° C. The energy-assisted sequential ALD method described above is typically practiced at pressures between 0.001 mTorr and 600 Torr, and preferably between 1 mTorr and 100 Torr. The energy-assisted sequential ALD method described above is typically practiced at gas flow rates between 0 sccm and 20,000 sccm, and preferably between 0.1 sccm and 5000 sccm.

In another embodiment of the present invention, the three precursors (TEMA-Hf, TEMA-Ti, and TEMA-Si) are introduced into the process chamber. The process chamber may be adapted to hold a single substrate such as in a single-wafer system or the like, or the process chamber may be adapted to hold a plurality of substrates such as in a batch furnace, a mini-batch furnace, a multi-wafer processing system, or the like. The three precursors can be mixed in the gaseous form before introduction into the process chamber, or mixed inside the process chamber. In the embodiment the precursors are present together in the process chamber in one cycle, instead of independently and sequentially conveyed to the process chamber as described in the alternative embodiment above. The three precursors form a monolayer on the substrate(s) in a concentration proportional to their gas phase concentration and their surface reactivity. Excess precursor that does not form the monolayer is removed from the process chamber by any number of means. A suitable oxidizing reactant is then introduced to react with the monolayer. The oxidizing reactant may be ozone, oxygen, peroxides, water, air, nitrous oxide, nitric oxide, N-oxides, and mixtures thereof. Ozone and water are exemplary choices. Excess oxidizing reactant that does not react with the monolayer is removed from the process chamber by any number of means. The result is a HfSiTiOₓ layer with a specific relative concentration of Hf, Si, and Ti. During the next ALD cycle, the relative concentration in the gas phase of the three precursors may be changed by changing the process parameters of the three precursors. This will result in a second monolayer with a different relative concentration of Hf, Si, and Ti from the first. This teaching may be employed during each cycle of the deposition process to tailor the concentration of each component throughout the film.

The ALD method described above is typically practiced at temperatures between 20° C. and 800° C., and preferably between 150° C. and 400° C. The co-injection ALD method described above is typically practiced at pressures between 0.001 mTorr and 600 Torr, and preferably between 1 mTorr and 100 Torr. The co-injection ALD method cited above is typically practiced at total gas flow rates between 0 sccm and 20,000 sccm, and preferably between 0.1 sccm and 5000 sccm.

In another exemplary embodiment of the present invention, it is desirable to practice the present invention at temperatures below 200° C. Additional energy source is supplied to facilitate the reaction and compound formation. In this embodiment, the three precursors (TEMA-Hf, TEMA-Ti, and TEMA-Si) are introduced into the process chamber together in one cycle. As before, the process chamber may hold a single substrate or a plurality of substrates. Excess precursor that does not form the monolayer is removed from the process chamber by any suitable means. As before, a suitable oxidizing reactant is then introduced to react with the monolayer. Ozone and water are exemplary choices. To facilitate the reaction, an energy source is used. The energy source may be direct plasma, remote plasma, down-stream plasma, RF-plasma, microwave plasma, UV photons, vacuum UV (VUV) photons, visible photons, IR photons, and combinations thereof. The energy source forms a chemical species that is reactive at temperatures of <200° C. The energy source may be used directly in the process chamber or may act upon the reactant gas before it enters the process chamber. The inventors have termed this method as “Energy-assisted co-injection ALD.” Excess oxidizing reactant that does not react with the monolayer is removed from the process chamber by any number of means. The result is a HfSiTiOₓ layer with a specific relative concentration of Hf, Si, and Ti. During the next “ALD cycle”, the relative concentration in the gas phase of the three precursors may be changed by changing the process parameters of the three precursors. This results in a second monolayer with a different relative concentration of Hf, Si, and Ti from the first. This teaching may be employed during each cycle of the deposition process to tailor the concentration of each component throughout the film.

The energy-assisted co-injection ALD method cited above is typically practiced at temperatures between 20° C. and 800° C., and preferably between 20° C. and 200° C. The energy-assisted co-injection ALD method described above is typically practiced at pressures between 0.001 mTorr and 600 Torr, and preferably between 1 mTorr and 100 Torr. The energy-assisted co-injection ALD method described above is typically practiced at gas flow rates between 0 sccm and 20,000 sccm, and preferably between 0.1 sccm and 5000 sccm.

The present invention may be applied to many ALD sequences. Examples for two or three precursors and one or two reactant gases are shown in TABLE 1 below. In the table, the letter “A” represents hafnium component, “B” titanium component, “C” a component such as silicon, aluminum, zirconium, tantalum, lanthanum, or cerium, “O” an oxidizing agent such as O₃, and N a nitriding agent such as NH₃. “(A+B)” means that the chemicals (A, B) are premixed in either gaseous or liquid phase before being pulsed.

TABLE 1

| | | Pulse | | | | | |
|---|---|---|---|---|---|---|---|
| | | Number/Sequence | | | | | |
| Film # | Film | 1 | 2 | 3 | 4 | 5 | 6 |
| 1 | ABO | A | B | O | | | |
| 2 | ABO | A | O | B | O | | |
| 3 | ABO | B | A | O | | | |
| 4 | ABO | B | O | A | O | | |
| 5 | ABN | A | B | N | | | |
| 6 | ABN | A | N | B | N | | |
| 7 | ABN | B | A | N | | | |
| 8 | ABN | B | N | A | N | | |
| 9 | ABON | A | O | B | N | | |
| 10 | ABON | A | N | B | O | | |
| 11 | ABON | B | O | A | N | | |
| 12 | ABON | B | N | A | O | | |
| 13 | ABO | (A + B) | O | | | | |
| 14 | ABN | (A + B) | N | | | | |
| 15 | ABON | (A + B) | O | N | | | |
| 16 | ABON | (A + B) | N | O | | | |
| 17 | ABCO | A | B | C | O | | |
| 18 | ABCO | A | C | B | O | | |
| 19 | ABCO | B | C | A | O | | |
| 20 | ABCO | B | A | C | O | | |
| 21 | ABCO | C | A | B | O | | |
| 22 | ABCO | C | B | A | O | | |
| 23 | ABCO | A | O | B | O | C | O |
| 24 | ABCO | A | O | C | O | B | O |
| 25 | ABCO | B | O | C | O | A | O |
| 26 | ABCO | B | O | A | O | C | O |
| 27 | ABCO | C | O | A | O | B | O |
| 28 | ABCO | C | O | B | O | A | O |
| 29 | ABCO | A | B | O | C | O | |
| 30 | ABCO | A | C | O | B | O | |
| 31 | ABCO | B | C | O | A | O | |
| 32 | ABCO | B | A | O | C | O | |
| 33 | ABCO | C | A | O | B | O | |
| 34 | ABCO | C | B | O | A | O | |
| 35 | ABCO | A | O | B | C | O | |
| 36 | ABCO | A | O | C | B | O | |
| 37 | ABCO | B | O | C | A | O | |
| 38 | ABCO | B | O | A | C | O | |
| 39 | ABCO | C | O | A | B | O | |
| 40 | ABCO | C | O | B | A | O | |
| 41 | ABCN | A | B | C | N | | |
| 42 | ABCN | A | C | B | N | | |
| 43 | ABCN | B | C | A | N | | |
| 44 | ABCN | B | A | C | N | | |
| 45 | ABCN | C | A | B | N | | |
| 46 | ABCN | C | B | A | N | | |
| 47 | ABCN | A | N | B | N | C | N |
| 48 | ABCN | A | N | C | N | B | N |
| 49 | ABCN | B | N | C | N | A | N |
| 50 | ABCN | B | N | A | N | C | N |
| 51 | ABCN | C | N | A | N | B | N |
| 52 | ABCN | C | N | B | N | A | N |
| 53 | ABCN | A | B | N | C | N | |
| 54 | ABCN | A | C | N | B | N | |
| 55 | ABCN | B | C | N | A | N | |
| 56 | ABCN | B | A | N | C | N | |
| 57 | ABCN | C | A | N | B | N | |
| 58 | ABCN | C | B | N | A | N | |
| 59 | ABCN | A | N | B | C | N | |
| 60 | ABCN | A | N | C | B | N | |
| 61 | ABCN | B | N | C | A | N | |
| 62 | ABCN | B | N | A | C | N | |
| 63 | ABCN | C | N | A | B | N | |
| 64 | ABCN | C | N | B | A | N | |
| 65 | ABCON | A | O | B | O | C | N |
| 66 | ABCON | A | O | B | N | C | O |
| 67 | ABCON | A | N | B | O | C | O |
| 68 | ABCON | A | O | C | O | B | N |
| 69 | ABCON | A | O | C | N | B | O |
| 70 | ABCON | A | N | C | O | B | O |
| 71 | ABCON | B | O | C | O | A | O |
| 72 | ABCON | B | O | C | N | A | O |
| 73 | ABCON | B | N | C | O | A | O |
| 74 | ABCON | B | O | A | O | C | O |
| 75 | ABCON | B | O | A | N | C | O |
| 76 | ABCON | B | N | A | O | C | O |
| 77 | ABCON | C | O | A | O | B | O |
| 78 | ABCON | C | O | A | N | B | O |
| 79 | ABCON | C | N | A | O | B | O |
| 80 | ABCON | C | O | B | O | A | O |
| 81 | ABCON | C | O | B | N | A | O |
| 82 | ABCON | C | N | B | O | A | O |
| 83 | ABCON | A | N | B | N | C | O |
| 84 | ABCON | A | N | B | O | C | N |
| 85 | ABCON | A | O | B | N | C | N |
| 86 | ABCON | A | N | C | N | B | O |
| 87 | ABCON | A | N | C | O | B | N |
| 88 | ABCON | A | O | C | N | B | N |
| 89 | ABCON | B | N | C | N | A | O |
| 90 | ABCON | B | N | C | O | A | N |
| 91 | ABCON | B | O | C | N | A | N |
| 92 | ABCON | B | N | A | N | C | O |
| 93 | ABCON | B | N | A | O | C | N |
| 94 | ABCON | B | O | A | N | C | N |
| 95 | ABCON | C | N | A | N | B | O |
| 96 | ABCON | C | N | A | O | B | N |
| 97 | ABCON | C | O | A | N | B | N |
| 98 | ABCON | C | N | B | N | A | O |
| 99 | ABCON | C | N | B | O | A | N |
| 100 | ABCON | C | O | B | N | A | N |
| 101 | ABCO | (A + B + C) | O | | | | |
| 102 | ABCO | (A + B) | O | C | O | | |
| 103 | ABCO | (A + C) | O | B | O | | |
| 104 | ABCO | (B + C) | O | A | O | | |
| 105 | ABCO | C | O | (A + B) | O | | |
| 106 | ABCO | B | O | (A + C) | O | | |
| 107 | ABCO | A | O | (B + C) | O | | |
| 108 | ABCN | (A + B + C) | N | | | | |
| 109 | ABCN | (A + B) | N | C | N | | |
| 110 | ABCN | (A + C) | N | B | N | | |
| 111 | ABCN | (B + C) | N | A | N | | |
| 112 | ABCN | C | N | (A + B) | N | | |
| 113 | ABCN | B | N | (A + C) | N | | |
| 114 | ABCN | A | N | (B + C) | N | | |
| 115 | ABCON | (A + B + C) | O | N | | | |
| 116 | ABCON | (A + B + C) | N | O | | | |
| 117 | ABCON | (A + B) | O | C | N | | |
| 118 | ABCON | (A + B) | N | C | O | | |
| 119 | ABCON | C | O | (A + B) | N | | |
| 120 | ABCON | C | N | (A + B) | O | | |
| 121 | ABCON | (A + C) | O | B | N | | |
| 122 | ABCON | (A + C) | N | B | O | | |
| 123 | ABCON | B | O | (A + C) | N | | |
| 124 | ABCON | B | N | (A + C) | O | | |
| 125 | ABCON | (B + C) | O | A | N | | |
| 126 | ABCON | (B + C) | N | A | O | | |
| 127 | ABCON | A | O | (B + C) | N | | |
| 128 | ABCON | A | N | (B + C) | O | | |

In the table, each row represents a different process sequence to deposit the target film. Each column of the table lists gases that are introduced during that step of the sequence. An energy-assisted ALD, CVD, energy assisted CVD, PVD or reactive PVD can be used.

In another embodiment of the present invention, the three precursors (TEMA-Hf, TEMA-Ti, and TEMA-Si) and the oxidizing reactant (e.g. ozone, water, or the like) are simultaneously introduced into the process chamber. The process chamber may be adapted to hold a single substrate such as in a single-wafer system or the like, or the process chamber may be adapted to hold a plurality of substrates such as in a batch furnace, a mini-batch furnace, a multi-wafer processing system, or the like. The three precursors can be mixed in the gaseous form before introduction into the process chamber, or mixed inside the process chamber. The three precursors form a film on the substrate(s) in a concentration proportional to their gas phase concentration and their surface reactivity. The result is a HfSiTiOₓ layer with a specific relative concentration of Hf, Si, and Ti. The inventors have characterized this method as “Gradient CVD.” During the time of the deposition, the relative concentration in the gas phase of the three precursors may be changed by changing the process parameters of the three precursors. This will result in a deposited material with a different relative concentration of Hf, Si, and Ti throughout. The process parameters may be chosen such that the film is deposited slowly, thus allowing concentration control on the atomic level. This teaching may be employed during the deposition process to tailor the concentration of each component throughout the film.

The gradient CVD method described above is typically practiced at temperatures between 20° C. and 800° C., and preferably between 150° C. and 400° C. The method described above is typically practiced at pressures between 0.001 mTorr and 600 Torr, and preferably between 1 mTorr and 100 Torr. The method described above is typically practiced at gas flow rates between 0 sccm and 20,000 sccm, and preferably between 0.1 sccm and 5000 sccm.

In another exemplary embodiment of the present invention, it is desirable to practice the present invention at temperatures below 200° C. In such embodiments, an additional energy source is supplied to facilitate the reaction and compound formation. In this embodiment, the three precursors (TEMA-Hf, TEMA-Ti, and TEMA-Si) and the oxidizing reactant (e.g. ozone, water, or the like) are simultaneously introduced into the process chamber. As before, the process chamber may hold a single substrate or a plurality of substrates. To facilitate the reaction, an energy source is used. The energy source may be direct plasma, remote plasma, down-stream plasma, RF-plasma, microwave plasma, UV photons, vacuum UV (VUV) photons, visible photons, IR photons, and the like, and combinations thereof. The energy source forms a chemical species that is reactive at temperatures of <200° C. The energy source may be used directly in the process chamber or may act upon the reactant gas before it enters the process chamber. The inventors have characterized this method as “Energy-assisted CVD.” The result is a HfSiTiOₓ layer with a specific relative concentration of Hf, Si, and Ti. The inventors have characterized this method as “Energy-assisted gradient CVD.” During the time of the deposition, the relative concentration in the gas phase of the three precursors may be changed by changing the process parameters of the three precursors. This will result in a deposited material with a different relative concentration of Hf, Si, and Ti throughout the film. The process parameters may be chosen such that the film is deposited slowly, thus allowing concentration control on the atomic level. This teaching may be employed during the deposition process to tailor the concentration of each component throughout the film.

The energy-assisted gradient CVD method described above is typically practiced at temperatures between 20° C. and 800° C., and preferably between 20° C. and 200° C. The energy-assisted gradient CVD method described above is typically practiced at pressures between 0.001 mTorr and 600 Torr, and preferably between 1 mTorr and 100 Torr. The energy-assisted gradient CVD method described above is typically practiced at gas flow rates between 0 sccm and 20,000 sccm, and preferably between 0.1 sccm and 5000 sccm.

In another embodiment of the present invention, the multi-component film is deposited using a PVD technique. In a first embodiment, three targets are used, one of Hf, one of Ti, and one of Si. A multi-component layer is formed by depositing Hf, Ti, and Si either simultaneously or sequentially. The PVD parameters are chosen so that only a few monolayers of material are deposited. A suitable oxidizing reactant is then introduced to react with the layer. The oxidizing reactant may be ozone, oxygen, peroxides, water, air, nitrous oxide, nitric oxide, N-oxides, and mixtures thereof. Ozone and water are exemplary choices. Excess oxidizing reactant that does not react with the layer is removed from the process chamber by any number of means. The result is a HfSiTiOₓ layer with a specific relative concentration of Hf, Si, and Ti. During the next “PVD ALD” cycle, the relative concentration of the three components may be changed by changing the PVD parameters of the three targets. This will result in a second layer with a different relative concentration of Hf, Si, and Ti from the first. This teaching may be employed during each cycle of the deposition process to tailor the concentration of each component throughout the film.

The PVD ALD method described above is typically practiced at temperatures between 20° C. and 800° C., and preferably between 20° C. and 200° C. The PVD ALD method described above is typically practiced at pressures between 0.001 mTorr and 600 Torr, and preferably between 1 mTorr and 100 Torr. The reactive-PVD ALD method described above is typically practiced at gas flow rates between 0 sccm and 20,000 sccm, and preferably between 0.1 sccm and 5000 sccm.

In another embodiment of the present invention, the multi-component film is deposited using a PVD technique. In a first embodiment, three targets are used, one of Hf, one of Ti, and one of Si. A multi-component layer is formed by depositing Hf, Ti, and Si either simultaneously or sequentially. The PVD parameters are chosen so that only a few monolayers of material are deposited. A suitable oxidizing reactant is then introduced to react with the layer during the PVD process. The oxidizing reactant may be ozone, oxygen, peroxides, water, air, nitrous oxide, nitric oxide, N-oxides, and mixtures thereof. Ozone and water are exemplary choices. The inventors have characterized this method as “Reactive-PVD ALD”. During the time of the deposition, the relative concentration of the three components may be changed by changing the process parameters of the three targets. This will result in a deposited material with a different relative concentration of Hf, Si, and Ti throughout. The process parameters may be chosen such that the film is deposited slowly, thus allowing concentration control on the atomic level. This teaching may be employed during the deposition process to tailor the concentration of each component throughout the film.

The reactive-PVD ALD method described above is typically practiced at temperatures between 20° C. and 800° C., and preferably between 20° C. and 200° C. The PVD ALD method cited above is typically practiced at pressures between 0.001 mTorr and 600 Torr, and preferably between 1 mTorr and 100 Torr. The PVD ALD method described above is typically practiced at gas flow rates between 0 sccm and 20,000 sccm, and preferably between 0.1 sccm and 5000 sccm.

In one embodiment, the present invention provides for methods for the deposition of a multi-layer, multi-component film stack with a dielectric constant (high-k) higher than that of SiO₂. The high-k film stack finds uses in the manufacture of semiconductor structures such as gates, capacitors, and the like. The methods provide for the introduction of a composition gradient throughout each of the films in the film stack during the deposition process for that film.

In one embodiment of the present invention, a multi-layer, multi-component film stack is formed to provide a high-k gate film stack. The various multi-layer stack comprises Si-rich layers, first barrier layers, bulk high-k layers, oxy-nitride layers, second barrier layers, electrode layers, and combinations thereof. Each layer is selected and developed to specifically optimize the performance of the multi-layer structure.

The gate dielectric material is typically grown or deposited directly on the surface of the substrate. The present example uses a silicon wafer as the substrate. The current SiO₂ gate dielectric is grown or formed by exposing the bare silicon substrate to an oxygen species at high temperatures (>600° C.). The silicon surface participates in the formation of the SiO₂ layer by acting as the source of silicon for the layer. The high-k dielectric materials of the present invention does not intentionally use the silicon surface as a source of any of the components of the film. Some embodiments involve the deposition of the first layer directly on the clean silicon surface. However, it is well known that silicon will form a native oxide of SiOₓ when exposed to ambient air. Therefore, for this discussion of the present invention, it is assumed that there is either a clean silicon surface, or a thin SiO₂ layer under the high-k film.

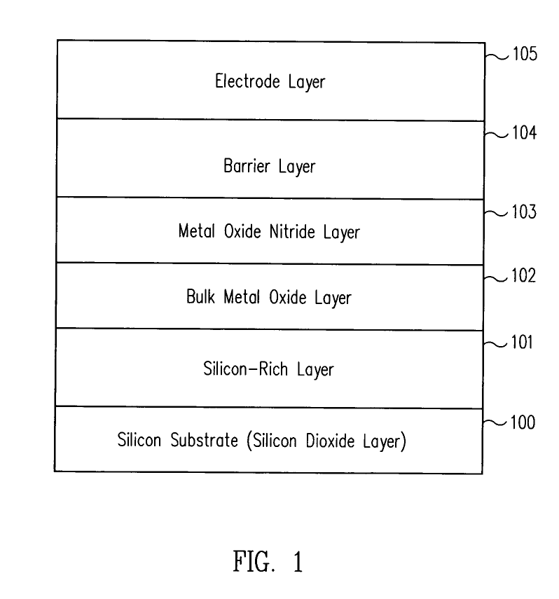

Referring to FIG. 1, the first layer that may optionally be deposited is a Si-rich layer. Exemplary materials include HfSiOₓ, TiSiOₓ, HfSiTiOₓ, AlSiOₓ, and the like. “Si-rich” means that [Si]>[Hf], [Si>[Ti], or [Si]>([Hf]+[Ti]). In one embodiment the silicon content may be up to 80%. The high concentration in this layer promotes chemical, physical, and electrical stability of the film adjacent the underlying substrate (100) during subsequent processing steps. This layer is not needed for combinations where the next layer does not react with the substrate. This layer is shown as (101) in FIG. 1. The Si concentration may be reduced as a function of distance away from the substrate so that the Si concentration is low at the top of the first layer.

The second layer (102) that is deposited is a bulk metal oxide layer. This material has the highest value of the dielectric constant (k) and determines the predominant dielectric properties of the multi-layer stack. Preferably, this layer contains no Si since it is known that the presence of Si in metal oxides decreases the value of k. Exemplary materials include HfOₓ, TiOₓ, TaOₓ, HfTaOₓ, TiTaOₓ, HfTiOₓ, HfAlOₓ, TiAlOₓ, TaAlOₓ, HfTaTiOₓ, and the like.

The third layer (103) that may optionally be deposited is a metal-oxide-nitride material. This material maintains a high value of k, but also includes nitrogen to prevent the diffusion of electrically active species such as B through the dielectric and into the underlying substrate. Boron diffusion is an issue when the electrode material is poly-Si doped with B. Exemplary materials include HfON, TiON, SiON, HfTiON, HfSiON, TiSiON, HfTiSiON, HfAlON, TiAlON, SiAlON, HfTiAlON, and the like.

The fourth layer (104) that may optionally be deposited is a barrier material. This material prevents the interaction of the dielectric material with the electrode material. The barrier material may have either dielectric or conductive properties. Exemplary materials include TiN, TaN, AlN, TiAlN, TaAlN, SiNₓ, Ru, RuO₂, CoWP, TaCN and the like.

The fifth layer (105) that may optionally be deposited is the electrode material. This layer serves to apply the voltage to the gate dielectric to activate the transistor. Exemplary materials include W, WN, Ru, NiSiₓ, doped-poly-Si and the like.

In one embodiment of the present invention, a multi-layer, multi-component film stack is formed to provide a high-k capacitor film stack. The various layers of the multi-layer stack comprise electrode layers, first barrier layers, bulk high-k layers, second barrier layers, electrode layers, and combinations thereof. Each layer is selected and developed to specifically optimize the performance of the multi-layer structure.

There are generally three basic types of capacitor structures. “SIS” capacitors refer to silicon-insulator-silicon capacitors where the electrodes are each made of doped silicon. “MIS” capacitors refer to metal-insulator-silicon capacitors where one electrode is a metal and the other electrode is made from doped silicon. Finally, “MIM” capacitors refer to metal-insulator-metal capacitors where the electrodes are each made of doped metal. As with the gate dielectric material mentioned above, the dielectric material must be chemically, physically, and electrically stable when in contact with both of the electrode materials under subsequent processing steps that may include high temperatures, typically 600° C. and above, during the manufacture of the semiconductor device. Silicon dioxide and silicon nitride have been uniquely well suited for this application for many years.

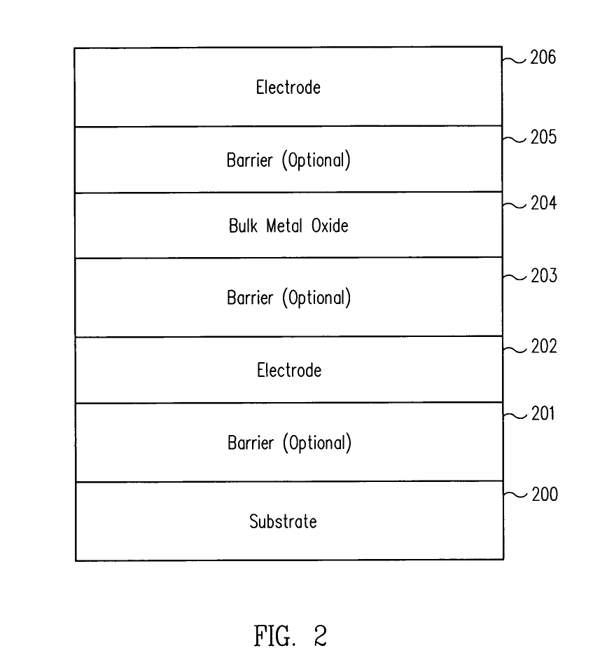

Referring now to FIG. 2, the first layer (201) that may optionally be deposited is a barrier material. This material prevents the interaction of the substrate material with the electrode material. The barrier material may have either dielectric or conductive properties. Exemplary materials include TiN, TaN, AlN, TiAlN, TaAlN, SiNₓ, Ru, RuO₂, CoWP, TaCN, NiSiₓ, and the like.

The second layer (202) that may optionally be deposited is the electrode material. This layer serves as one of the plates of the capacitor structure. Exemplary materials include W, WN, Ru, NiSiₓ, doped-poly-Si and the like.

The third layer (203) that may optionally be deposited is a barrier material. This material prevents the interaction of the dielectric material with the electrode material. The barrier material may have either dielectric or conductive properties. Exemplary materials include TiN, TaN, AlN, TiAlN, TaAlN, SiNₓ, Ru, RuO₂, CoWP, TaCN, NiSiₓ, and the like.

The fourth layer (204) that is deposited is a bulk metal oxide layer. This material has the highest value of the dielectric constant (k) and determines the predominant dielectric properties of the multi-layer stack. Exemplary materials include HfOₓ, TiOₓ, TaOₓ, HfTaOₓ, TiTaOₓ, HfTiOₓ, HfAlOₓ, TiAlOₓ, TaAlOₓ, HfSiOₓ, TiSiOₓ, TaSiOₓ, AlSiOₓ, HfSiTiTaOₓ, HfTaTiOₓ, and the like.

The fifth layer (205) that may optionally be deposited is a barrier material. This material prevents the interaction of the dielectric material with the electrode material. The barrier material may have either dielectric or conductive properties. Exemplary materials include TiN, TaN, AlN, TiAlN, TaAlN, SiNₓ, Ru, RuO₂, CoWP, TaCN, NiSiₓ, and the like.

The sixth layer (206) that may optionally be deposited is the electrode material. This layer serves as one of the plates of the capacitor structure. Exemplary materials include W, WN, Ru, NiSiₓ, doped-poly-Si and the like.

The foregoing descriptions of specific embodiments of the present invention have been presented for the purpose of illustration and description. They are not intended to be exhaustive or to limit the invention to the precise forms disclosed, and obviously many modifications, embodiments, and variations are possible in lights of the above teaching. It is intended that the scope of the invention be defined by the Claims appended hereto and their equivalents.

What is clamed is:

1. A dielectric film comprising a hafnium component and/or a titanium component and/or a silicon component and/or an oxygen component and/or a nitrogen component.

2. The dielectric film of claim 1 which comprises a hafnium component, a titanium component, a silicon component, an oxygen component, and a nitrogen component.

3. A dielectric film comprising a composition of HfTiSiₓO_{y}N_{z} wherein x, y, and z represent a number from 0 to 2, respectively.

4. A method of forming a film on a substrate, characterized in that two or more precursors, at least one of the precursors containing a titanium containing chemical component, are conveyed to a process chamber together or sequentially and form a mono-layer on a surface of the substrate, wherein the amount of each of the precursors conveyed to the process chamber is selectively controlled such that a desired composition gradient is formed in the film.

5. The method of forming a film according to claim 4 wherein the film is formed by any one of ALD, energy assisted ALD, CVD, energy assisted CVD, PVD or reactive PVD.

6. The method of claim 5 wherein the film is formed at a temperature between 20° C. to 800° C. and a pressure between 0.001 mTorr to 600 Torr.

7. A semiconductor film stack comprising:
a substrate comprised of Si, SiO₂ or SOI;
a first layer atop the substrate and comprised of any one of HfSiOₓ wherein the concentration of Si is greater than the concentration of Hf, TiSiOₓ wherein the concentration of Si is greater than the concentration of Ti, AlSiOₓ wherein the concentration of Si is greater than the concentration of Al, or HfSiTiOₓ wherein the concentration of Si is greater than the total concentration of Hf plus Ti, and HfTiOₓ;
a second layer atop the first layer and comprised of any one of HfOₓ, HfTiOₓ, HfAlOₓ, TiOₓ, HfTaTiOₓ, TaOₓ, HfTaOₓ, TiTaOₓ, TiAlOₓ, or TiAlOₓ;
a third layer atop the second layer and comprised of any one of HfON, TiON, SiON, HfTiON, HfSiON, TiSiON, or HfTiSiON;
a forth layer atop the third layer and comprised of any one of TiN, TaN, AlN, TiAlN, TaAlN, SiNₓ, Ru, RuO₂, CoWP, or TaCN; and
a fifth layer atop the fourth layer and comprised of any one of W, WN, Ru, NiSiₓ, or doped-Si.

8. A dielectric film comprising a silicon-rich bottom layer; a nitrogen-rich top layer; and a hafnium titanate layer formed between said top and bottom layers wherein in the silicon-rich bottom layer, the concentration of silicon is greater than the concentration of hafnium, titanium or nitrogen, or combination thereof.

9. The dielectric film of claim 8 wherein the concentration of silicon decreases as a function of distance away from a substrate atop which the dielectric film is formed.

10. The dielectric film of claim 8 wherein the concentration of silicon in the silicon-rich bottom layer is up to 80 percent.

11. The dielectric film of claim 8 wherein in the hafnium-titanate layer, the concentration of silicon is smaller than the concentration of hafnium, titanium, nitrogen or combination thereof.

12. A semiconductor film stack comprising:
a substrate comprised of doped-Si, or metal;
a first layer atop the substrate and comprised of any one of TiN, TaN, AlN, TiAlN, TaAlN, SiNₓ, Ru, RuO₂, CoWP, NiSiₓ, or TaCN;
a second layer atop the first layer and comprised of any one of W, WN, Ru, NiSiₓ, or doped-Si.
a third layer atop the second layer and comprised of any one of TiN, TaN, AlN, TiAlN, TaAlN, SiNₓ, Ru, RuO₂, CoWP, NiSiₓ, or TaCN;
a fourth layer atop the third layer and comprised of any one of HfOₓ, HfTiOₓ, HfAlOₓ, TiOₓ, HfTaTiOₓ, TaOₓ, HfTaOₓ, TiTaOₓ, TiAlOₓ, TiAlOₓ, HfSiOₓ, TiSiOₓ, TaSiOₓ, AlSiOₓ, or HfSiTiTaOₓ;
a fifth layer atop the fourth layer and comprised of any one of TiN, TaN, AlN, TiAlN, TaAlN, SiNₓ, Ru, RuO₂, CoWP, or TaCN; and
a sixth layer atop the fifth layer and comprised of any one of W, WN, Ru, NiSiₓ, or doped-Si.

13. A method of forming a film on one or more substrates in a process chamber, comprising:
exposing the one or more substrates to one or more precursors to form a monolayer of the precursors on the substrate, and purging the process chamber of excess precursors;
exposing the one or more substrates to one or more reactants to react with the monolayer of the precursors on the substrate to form a compound, and purging the process chamber of excess reactants; and
repeating said exposing steps until the desired thickness of film is formed, wherein the concentration of each precursor is controlled during each repetition of the step so that a composition gradient of each precursor is established throughout the thickness of the film.

14. A semiconductor film comprising:
a substrate comprised of Si, SiO₂ or SOI; and
a first layer atop the substrate comprised of any one of HfOₓ, HfTiOₓ, HfAlOₓ, TiOₓ, HfTaTiOₓ, TaOₓ, HfTaOₓ, TiTaOₓ, TiAlOₓ, or TiAlOₓ.

15. The film of claim 14 further comprising:
an interlayer formed between said substrate and said first layer and comprised of any one of HfSiOₓ wherein the concentration of Si is greater than the concentration of Hf, TiSiOₓ wherein the concentration of Si is greater than the concentration of Ti, AlSiOₓ wherein the concentration of Si is greater than the concentration of Al, or HfSiTiOₓ wherein the concentration of Si is greater than the total concentration of Hf plus Ti and HfTiOₓ.

16. The film of claim 15 further comprising a second layer formed atop the first layer and comprised of any one of HfON, TiON, SiON, HfTiON, HfSiON, TiSiON, or HfTiSiON.

17. The film of claim 16 further comprising a third layer atop the second layer and comprised of any one of TiN, TaN, AlN, TiAlN, TaAlN, SiNₓ, Ru, RuO₂, CoWP, or TaCN.

18. The film of claim 17 further comprising a fourth layer atop the third layer and comprised of any one of W, WN, Ru, NiSiₓ, or doped-Si.
